(19) United States
(12) Patent Application Publication
(10) Pub. No.: US 2017/0131899 A1
(43) Pub. Date: May 11, 2017

(54) Scale Out Storage Architecture for In-Memory Computing and Related Method for Storing Multiple Petabytes of Data Entirely in System RAM Memory

(71) Applicants: Emilio Billi, San Jose, CA (US); Vittorio Rebecchi, Galliate (IT)

(72) Inventors: Emilio Billi, San Jose, CA (US); Vittorio Rebecchi, Galliate (IT)

(73) Assignee: A3Cube, Inc., San Jose, CA (US)

(21) Appl. No.: 14/935,446

(22) Filed: Nov. 8, 2015

(51) Int. Cl. G06F 3/06; G11C 7/10

(52) U.S. Cl. CPC G06F 3/061; G11C 7/1072; G06F 3/0655; G06F 3/0629; G06F 3/0689

(57) ABSTRACT

A high performance, linearly scalable, software-defined, RAM-based storage architecture designed for in-memory RAM based petascale systems, including a method to aggregate system RAM memory across multiple clustered nodes. The architecture realizes a parallel storage system where multiple petabytes of data can be hosted entirely in RAM memory. The resulting system eliminates the scalability limitation of any traditional in-memory approach using a file system based scale-out approach with low latency, high bandwidth, and scalable IOPS running entirely in RAM.

### BACKGROUND OF THE INVENTION

Field of Invention

The present invention describes a software defined massively parallel clustered storage realized using the systems random access memory (RAM) for application acceleration and ultra-fast data access. The resulting distributed RAM storage can scale across 1000s of nodes supporting up to exabytes of data entirely hosted in RAM disk. This pure RAM memory based storage provides a full concurrent, scalable parallel data access to the data present on each storage node.

Description of Related Art

High-performance computing systems require storage systems capable of storing multiple petabytes of data and delivering that data to thousands of users at the maximum speed possible. High performance emerging analytics applications require data access with the minimum latency possible in combination with a scalable file system organization. A classic example is the architecture of analytics engines like Hadoop and its HDFS. Many companies are moving the data storage to RAM memory to achieve the speed required by modern applications.

Many existing in-memory approaches require a complete porting of applications into the new in-memory capable software to take advantage of the acceleration provided by the RAM memory. Just, for example, but not limited to, the in-memory databases. This approach is not able to accelerate the existing applications that are not designed to run in-memory. The cost for the porting and the non-universal in-memory application make this approach expensive and complex to manage. Also in the easiest cases the porting of an application from a platform to another one is not trivial and requires an accurate plan of action.

There is a need in the art for a whole new view of how in-memory data access can be realized, providing a simple way to use the memory as an application accelerator for I/O intensive software. We need a scalable memory approach that permits to any application without modification to store data and perform operations entirely in memory without using the memory as a cache but as the main storage for the data.

There is the need in the art for an RAM memory based storage system that can scale in capacity and performance linearly. This system must scale across 1000s of nodes, without introducing I/O bottlenecks, and is as a generic standard storage devices from the application point of view.

There is the need for an RAM based storage that provides protection from the risk data loss in case of server problems like, but not limited to reboot or power loss.

### SUMMARY

Embodiments of this invention provide a scale-out RAM disk that can create a global namespace across 1000s of clustered servers realizing a parallel storage entirely hosted in RAM. This distributed scalable RAM disk appear as generic storage devices. The resulting device is used as a standard storage device and can be accessed by any unmodified application. The primary mechanism used to achieve this result is to transform a standard RAM disk into a virtual storage device based on the system RAM. The virtual storage device uses a standard POSIX file system, like, but not limited to, Linux ZFS, realizing a file system completely in RAM memory (Virtual in-RAM device). The resulting virtual in-RAM device scales, creating a unified global shared namespace, across multiple clustered nodes, using, for example, but not limited to, scale-out software defined platforms. There are many applications that can take advantages of this RAM based scalable storage architecture like, but not limited to, traditional SQL database with large datasets. Other applications such as, but not limited to, web services can use this scale out in memory storage as a giant distributed shared alternative to a cache system. A quantitative example can be done to emphasize the benefit of this approach. Imagine, for example, but not limited to, that a web page requires 200 sequential accesses to different services to create the page outfit for the end user. A traditional storage system with traditional spinning drive can provide about 1000 sequential access on the data; this means that you can serve only five users/pages per seconds. Using the RAM as data storage the number of sequential access that you can do per second are close to 1,000,000, this means that you can serve 5000 pages/users per seconds with the same infrastructure. This dramatic reduction of the latency access and the elimination of the constraints related to the amount of memory available on a single server permits a new level of scalability to any application.

Exposing the RAM memory as a generic storage device has many benefits compared to the traditional cache coherent based memory, like, but not limited to, scalability, flexibility, and usability. CPUs need that the access to the RAM memory is extremely fast. Clustered cache coherent system introduces high latency in the memory access across the nodes compared to the local access latency. This added latency affects both performance and system scalability negatively. Other than that, the cache coherency protocol introduces a big traffic overhead across the nodes just for the system synchronization. RAM memory as a file system, on the contrary, eliminates all these problems. Applications are designed taking into consideration that a file system device is slow compared to the system memory, for that reason providing a RAM based file system device instead of a traditional one permits to obtain a dramatic acceleration. The scalability of RAM-based storage devices does not have the limitation of the addressability of the CPUs memory controller, typically 256 terabytes (48 bits). The RAM-based device capacity is related to the file system scalability typically up to 16 bits (Exabytes). The absence of the cache coherency protocol permits to aggregate petabytes of memory without performance degradation. The access to a file system completely based on an RAM device has extremely low latency. Low latency access permits to achieve a very high number of IOPS. The performance of any IO-intense application like, but not limited to, analytics and database applications are linearly proportional to the IOPS; this means that this type of application is latency driven. In the past, capacity and throughput were the major challenges when dealing with data growth. Today capacity and throughput are “commodity”; the new performance metric is the latency.

In one aspect, embodiments of the invention relate to a software-defined scale out RAM based storage system. The invention provides a method to create a RAM-based virtual storage device that appears as a common storage device, like but not limited to, a standard flash memory based disk. The virtual storage device can be formatted using a standard POSIX file system, like but not limited to, ZFS or EXT4 or XFS. The file system resides entirely in RAM memory.

In some embodiments, the storage nodes aggregate the local RAM based devices realizing a distributed parallel RAM based scale-out clustered storage system. The resulting aggregated volume is accessible from each single node. Each node mounts a local virtual device. The resulting capacity of the aggregated virtual device is the sum of the capacity of each single RAM-based devices locally present in each cluster node. Each single node can access the virtual aggregated volume in a concurrent parallel way.

In some embodiments, the storage nodes aggregate the local RAM based devices realizing a distributed parallel RAM based scale-out clustered storage system, using for example, but not limited to, a scale-out software defined storage. This aggregation can be done, for example, but not restricted to, without the use of a metadata server. This architecture can use, for example, but not limited to, a hashing algorithm to maintain the information about files in the global shared volumes. This architecture realizes a fully symmetric scale-out system.

In some embodiments, the scale out RAM storage can be exported using, for example, but not limited to, NFS, iSCSI, CIFS protocols. The system must use an opportune fabric network like but not limited to, a low latency interconnects or an RDMA capable one. The result is an NAS-like parallel storage system entirely realized on RAM based devices aggregated in a single parallel global file system.

In some embodiments, the scale out RAM based devices is created inside the computing server nodes realizing a parallel converged system. Each single node in the cluster is a computing node and a storage node at the same time. Each single node can provide an RAM-based device with the method described in this invention. The RAM-based devices are aggregated together creating a common virtual volume that is shared locally by all the nodes. The computing processes that run on each node have access directly and concurrently to the virtual global volume. The proposed architecture provides extremely low latency in data access (reading/writing) and a scalable bandwidth.

In some embodiments, RAM disks can be mirrored on a secondary non-volatile memory device, like, but not limited to, NVMe or SSD drive. This mirroring realizes a secure backup for the data stored in the “in-memory” file system. RAM-based devices can lose the data in case of absence of power in the server or the system. The content of the memories is, by its nature, volatile. To provide a robust storage system using RAM-based devices we need to adopt a strategy to maintain the content of the device also in case of failure. The present invention provides a method to make a copy of the data, during the writing phase in a secondary, fast and non-volatile device.

In some embodiments, the scale out RAM disks is used as the main repository for data and not as a data cache, like, but limited to, Memcached architectures.

### BRIEF DESCRIPTION OF THE DRAWINGS

FIG. 1 Shows, in a preferred embodiment, a logical flow that describes the realization of the RAM storage starting from the ram disk creation and preparation.

FIG. 1a. Shows, in a preferred embodiment, a logical representation of the RAM disk.

FIG. 1b. Shows, in a preferred embodiment, a logical representation of how the RAM disk modification permits the realization of the RAM-based device.

FIG. 2 Shows, in a preferred embodiment, a logical representation of the creation of the RAM-based device.

FIG. 3 Shows in a preferred embodiment, a logical representation of how a clustered system can be realized starting from the RAM-based devices

FIG. 4 Shows, in a preferred embodiment, a logical representation of how the in memory devices are organized to realize the clustered RAM storage

FIG. 5 Shows, in a preferred embodiment, a logical representation of how the persistence of the data in the RAM-based device is realized using a secondary non-volatile storage device

FIG. 6 Shows, in preferred embodiments, a logical representation of how a real scale-out an RAM-based system can work in practical embodiments.

### DETAILED DESCRIPTION OF THE PREFERRED EMBODIMENTS

The figures described above, and the written description of specific structures and functions below are not presented to limit the scope of what Applicants have invented or the scope of the appended claims. Rather, the figures and written description are provided to teach any person skilled, in the art, and in the technology here described, to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location, and from time to time. While a developer's efforts might be complex and time-consuming in an absolute sense, such efforts would be, nevertheless, a routine undertaking for those of skill in this art having the benefit of this disclosure. It must be understood that the inventions disclosed and taught within are susceptible to numerous and various modifications and alternative forms.

The current designs for software-defined storage (SDS) do not focus on providing petabyte-scale converged storage systems using RAM as the main storage device. Merging in-memory computing relays on the utilization of the system RAM memory as a caching system and all the mechanisms are proprietary for each specific software like, but not limited to, in memory databases and libraries. This approach presents at least two major limitations: the scalability of the memory caching across multiple nodes in a clustered scenarios and the need to use a specific software. In most cases migration from a traditional database system to an in memory one requires complex data and application porting, which is usually very expensive and risky.

The present invention provides a different method to achieve the same performance of an in-memory application without using a dedicated application or library and without modifying the application itself. The main idea behind this invention is to provide a scalable file system that can scale across multiple nodes entirely deployed in the system RAM memory. The result is a scale-out parallel file system in RAM that can scale to 1000s of nodes and can be used by any application as data repository. The speed of the access is, exactly like in the in-memory system, the speed of the system RAM. The capacity, on the contrary, is not limited to the available amount of the memory on the single server but scales across all the clustered nodes.

Traditional RAM drives offer a good starting point to realize a memory based storage system, but they do not scale across multiple system nodes. The file system used by default in the Linux systems to build RAM drive is not fully POSIX compliant. The Linux POSIX shared memory, used by many applications as file system based shared memory, is also limited to the capacity of the memory on a single node. Providing a scale-out clustered storage system that can aggregate the capacity of the RAM disks in each clustered server, into a global RAM-based virtual shared volume, offers a perfect alternative to the existing in-memory approaches. The resulting system is a virtual RAM based volume distributed and shared across all the clustered nodes used as a standard storage device by unmodified applications. It represents an entirely new way of organizing storage and data access. All information is in DRAM at all times. The virtual RAM-based sale-out virtual volume is not a cache like Memcached. The data is not stored on an I/O device, like, but not limited to, flash memory. The system RAM is the permanent home for data.

Most of the SDS solution focuses on providing a cheaper solution compared to the traditional storage system. This invention instead realizes a method to create software-defined RAM-based storage that represents an alternative to the existing in-memory software architecture providing a universal application transparent methods to use memory acceleration for any unmodified application.

The present invention provides a method and design technique to build a giant storage array using system RAM as a primary storage device that scales across 1000s of nodes.

Modern real-time application and high-performance analytics require very fast access to the data, very low latency and high bandwidth. There are also other more traditional applications, like but not limited to, SQL databases, that require accessing their data sets as fast as possible. Emerging computing challenges like, but not limited to, genomics, proteinomics, anti-fraud detection require fast data access, high bandwidth, and low latency.

Today the typical solution is to use software that is designed to store data in-memory like, but not limited to, in-memory databases.

These types of software approach require the use of specific software and application and do not provide a general-purpose acceleration to standard applications.

In the present invention, we introduce the concept of an RAM based scale-out parallel storage based on the aggregation of standard RAM disk modified to be used as devices and aggregate together realizing a scalable storage.

This architecture and related method permit to scale on 1000s of clustered nodes realizing a new kind of storage and a new type of computing/storage converged architecture that eliminate the needs

Traditional RAM disks become virtual RAM-based devices. The RAM-based devices can be formatted using a standard file POSIX compliant system and aggregated and disaggregated in an elastic way creating a global shared namespace. The resulting system provides concurrent parallel data access across all the clustered nodes exposing a globally shared storage volume that can be used by applications without any modification.

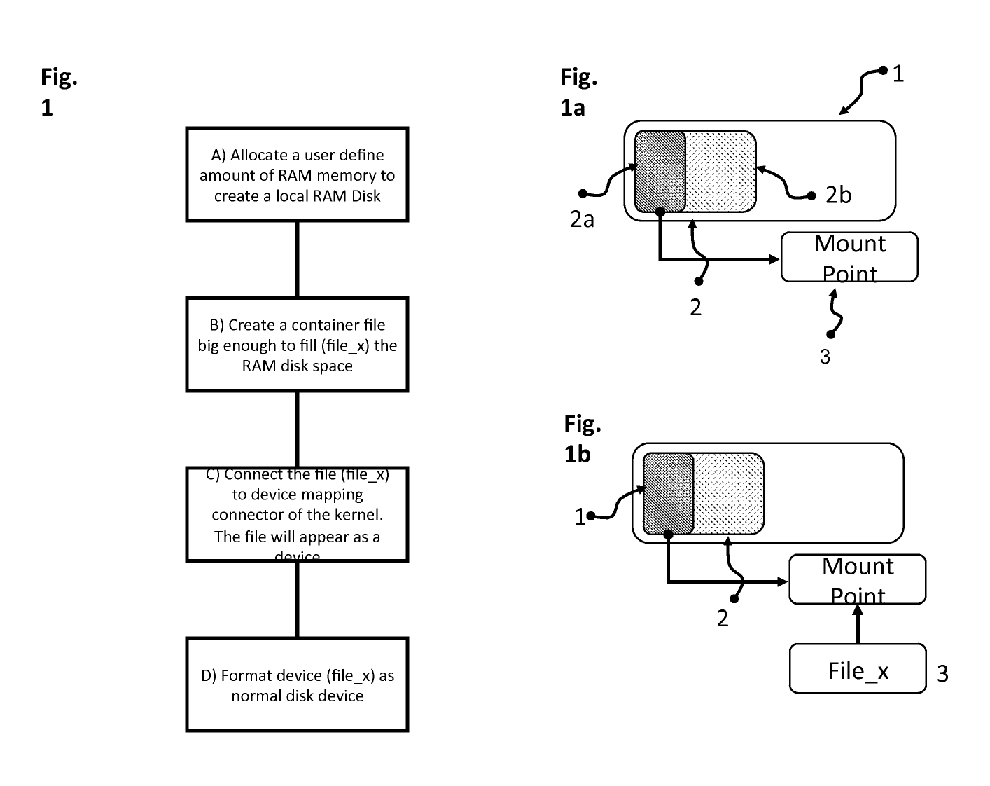

FIG. 1 Shows, in a preferred embodiment, a logical flow for the realization of the RAM storage starting from the creation and preparation of the RAM disk in a single server. A portion of the system RAM memory is allocated using for example, but not limited to, the traditional mechanism for the RAM disk creation under Linux (A). The creation of an RAM disk can be done using the standard Linux methods, that are not the object of the present invention. The RAM disk is created and activated before the file system services are activated. A file (B) is set up to and used as a container. The use of a container inside the RAM disk permits to manage the RAM disks and create the RAM devices without involving the kernel in the operations. Avoiding the utilization of the Linux Kernel in the creation of the RAM disks permits to realize an RAM-based device that is elastically configurable without the need to recompile the Linux kernel. The main benefit of this approach is that is possible to configure a RAM disk using for example, but not limited to, a collection of software scripts. The container file should be large enough to fit with the RAM disk dimension. The file is mapped to a virtual RAM-based device using the Linux Kernel operations. (C) The file appears as a device. This RAM-based device is a standard storage device (D) formatted with a POSIX compliant file system like any standard storage device.

FIG. 1a Shows, in a preferred embodiment, a scheme of how to create and organize the RAM-based storage. The server (1) has some available RAM memory (2) that can be used to create an RAM disk (2a). Different methods are available in the operating system for the creation of an RAM disk, for example, the device RAM disk, driven by the OS Kernel and the RAM temporary files (tmpfs). The device RAM disk presents some limitation due to the need for some parameters in the OS Kernel (e.g. but not limited to CONFIG_BLK_DEV_RAM_COUNT=1 and CONFIG_BLK_DEV_RAM_SIZE=10485760). These Kernel parameters make the dynamic configuration of a RAM disk very complex. The present invention in a preferred embodiments uses the temporary RAM files (tmpfs) but can also work with other methods. The RAM disk created is mounted into the Linux file system tab as a standard drive.

FIG. 1b. Shows, in a preferred embodiment, the RAM disk (1) mounted in his mount point (2) mapped to file to realize a memory container (3).

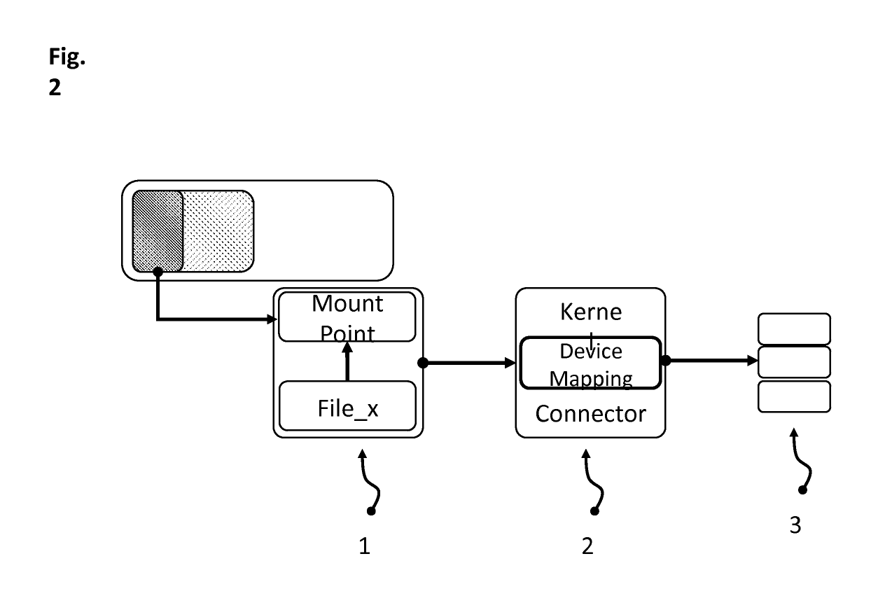

FIG. 2 Shows, in a preferred embodiment, how the memory container (1) is mapped. This operation is done using the concept of device loops (2) in a virtual storage device (3).

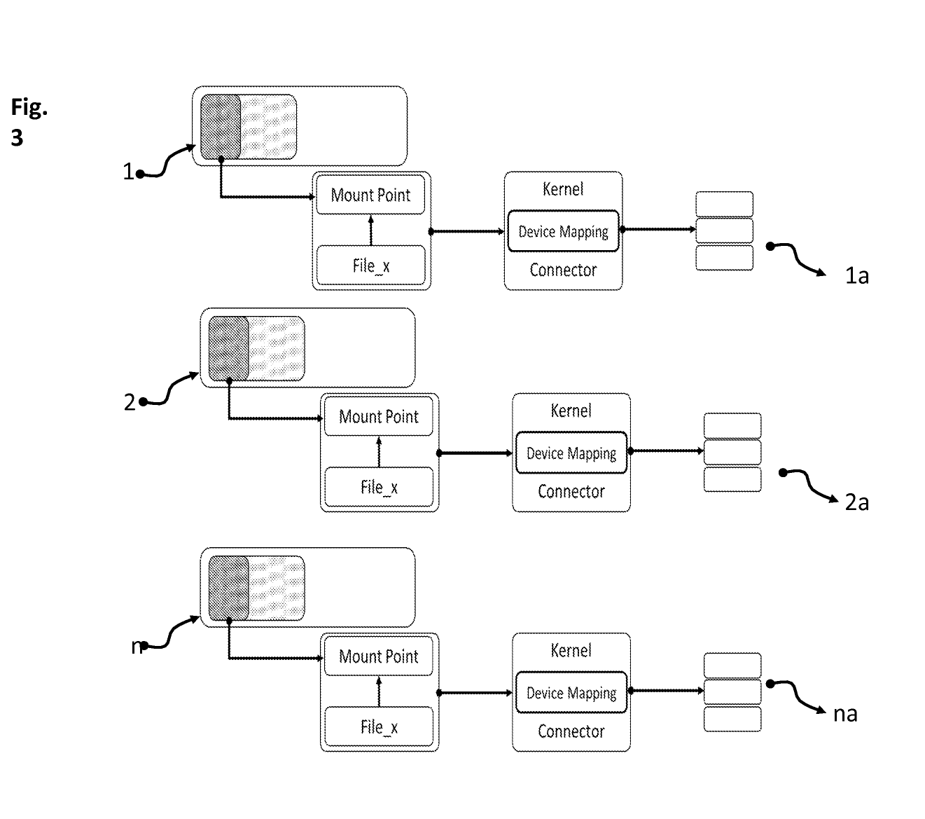

FIG. 3 Shows in a preferred embodiment, multiple clustered servers (1), (2), (n) with corresponding virtual storage devices each (1a), (2a), (na). These virtual devices appear as standard storage devices aggregated across all the clustered servers (1), (2), (n). The aggregation is realized using, for example, but not limited to, a scale-out software-defined storage software.

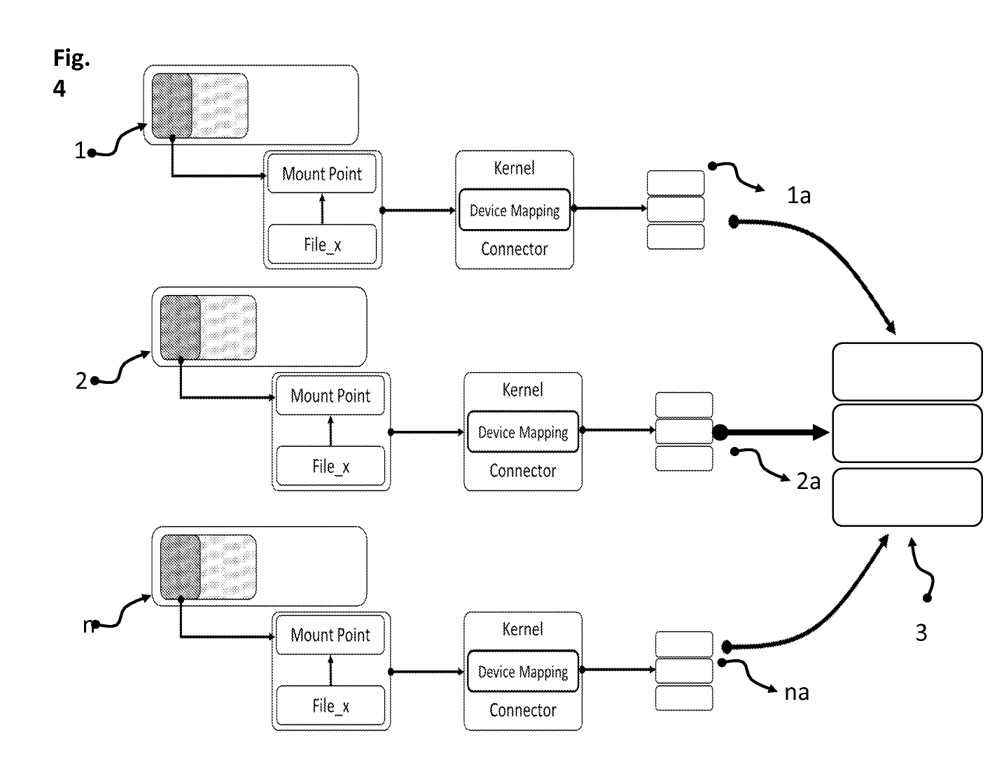

FIG. 4 Shows, in a preferred embodiment, how the devices (1a,1b,1c), inside the servers (1, 2, 3), appear. The device is a single virtual shared storage volume (3). The shared virtual device (3) has many important features. The resulting device is shared across all the clustered nodes, it can be accessed concurrently from any nodes, it provide scalable bandwidth and scalable IOPS. This device can, also, be used by any unmodified application as a standard storage device and can be exported using storage protocols like, but not limited to, NFS, CIFS, iSCSI.

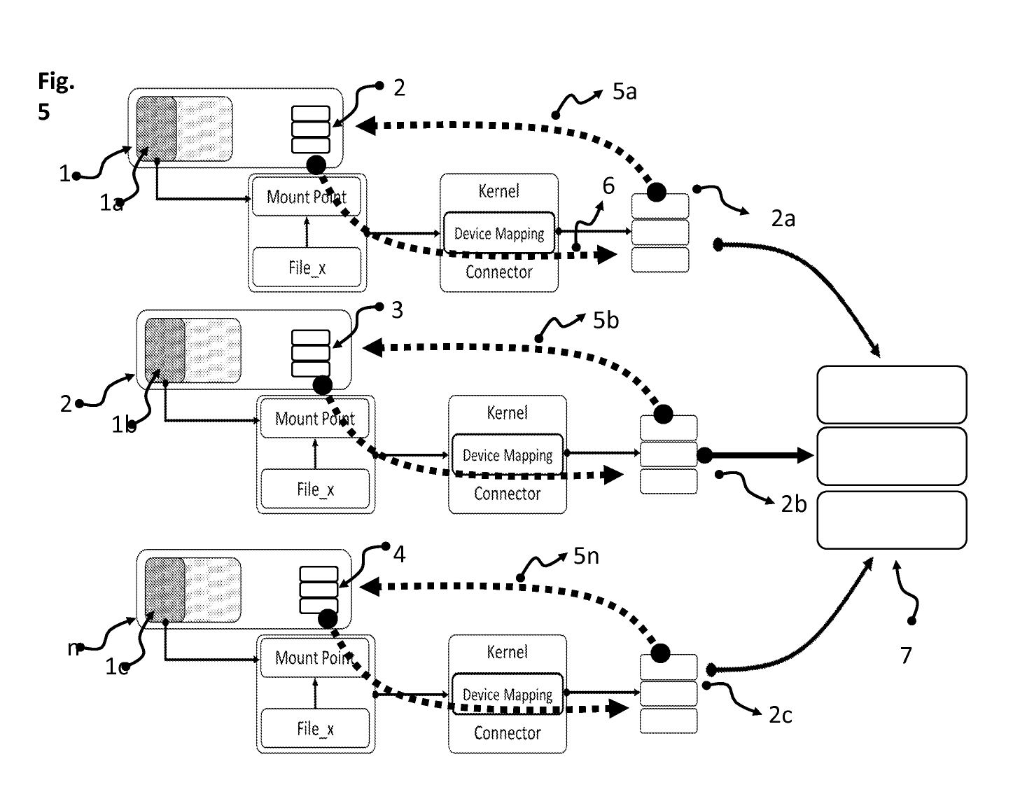

FIG. 5 Shows, in a preferred embodiment, how the RAM storage can be organized to provide a reliable data mirroring that can be used as a safe-copy in case of system failure. The servers (1), (2), (3) can provide an additional storage device like, but not limited to a fast SSD disk. This extra disk is organized to match the dimension of the local RAM disk (1a), (1b), (1c). The dimensional matching can be realized using for example, but not limited to, a dedicated disk partition, built on demand, that match with the dimension of the RAM-based device. The system is configured to make a copy of any data written to the RAM-based device (2a), (2b), (2c). This operation can be done using for example, but not limited to, a software function (5a). In case of system failure, after the system has recovered, the same mechanism or a different one (6) is used to copy the data back into the RAM-based device. The mechanism copies the data in the way to repristinate the status of the device before the system failure.

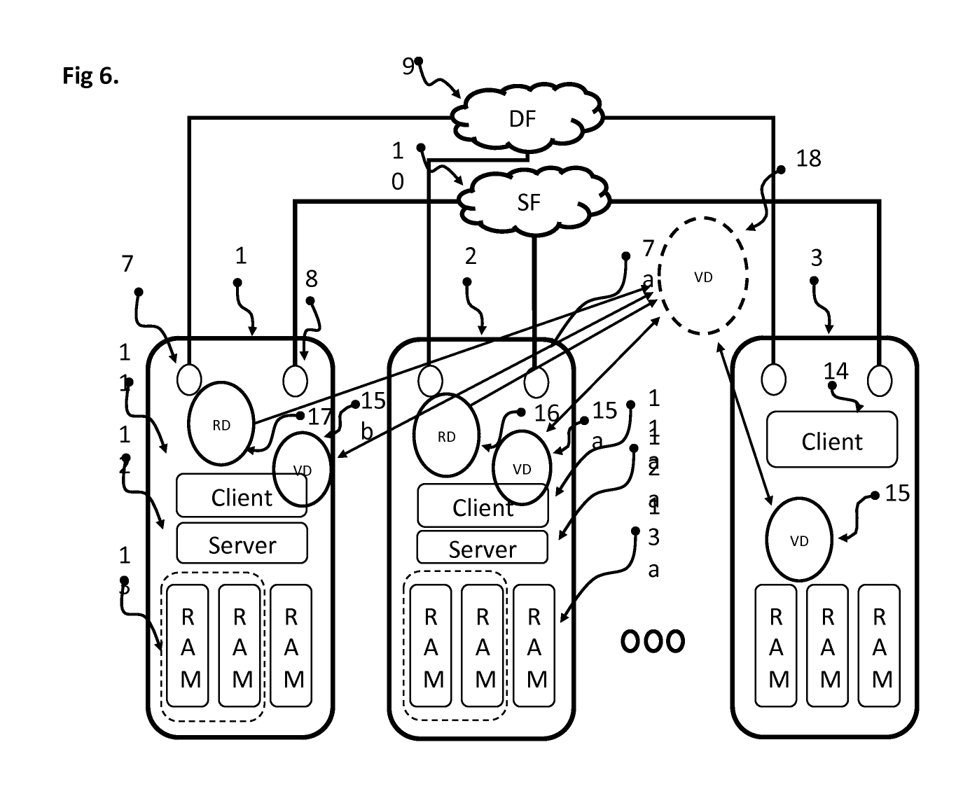

FIG. 6 Shows, in a preferred embodiment, how the scale-out RAM-based storage can be deployed. A plurality of servers (1), (2), (3) are connected using for example, but not limited to a high-speed network used as storage fabric (10). The storage fabric can be, for instance, but not limited to, preferably separate from the data center fabric (9). The separation between the storage fabric and the data fabric or datacenter fabric permits to achieve the highest performance. The storage fabric creates a clustered system. The servers, for example, but not limited to (1) and (2) export a portion of their local memory. This part of the local memory generates the RAM-based device. These RAM-based memory devices are aggregated and managed, across the clustered servers, using a client-server model. This client-server model can be derived, but not limited to, a standard mechanism used by many software defined storage systems and it is not the object of the present invention. There are some preferred methods that are not part of the present application. The servers (1) and (2) have both the client, and the server enabled at the same time. The server (3), for example, but not limited to, on the contrary, has only the client side. The methods described in this invention permit to create a local RAM-based device, for example, but not limited to, (16), (17) in the servers (1) and (2). The server (3), for example, but not limited to, do not create any local RAM-based device. Each RAM-based devices (17) and (16) converge into a resulting common shared virtual RAM-based device (18). This joint shared virtual device (18) appears as a locally mounted device (15),(15a),(15b). This local device is common to all the clustered servers (1),(2),(3). The server (3) access the same volume (18) as the other ones, using for example, but not limited too, a high-speed storage network, like, but not limited too, RDMA. The server (3) can use the RAM-based shared device as local ultra-fast file system based on RAM without using the local RAM. The described architecture permits to use the server with a significant quantity of RAM by the server with a small amount of RAM as fabric attached RAM-based storage devices. The suggested architecture can realize converged RAM-device fabric attached systems.

1. A high performance, linearly scalable, software-defined, scale out RAM-based shared and parallel storage architecture as described in the present application.

2. A high performance, linearly scalable, software-defined, RAM-based storage architecture outlined in the claim 1, designed for in-memory petascale systems, where the aggregated system RAM memory scales across multiple clustered nodes, using an RAM disk based storage device as building block.

3. A high performance, linearly scalable, software-defined, RAM-based storage architecture as described in the claim 1, that realize a parallel storage system where petabytes of data can be hosted entirely in RAM memory and accessed using a high-speed file system entirely in RAM.

4. A high performance, linearly scalable, software-defined, scale out RAM-based shared and parallel storage architecture as described in the present application that can be formatted with any standard POSIX file system and used as a conventional scale out storage
